(19) United States
(12) Patent Application Publication
(10) Pub. No.: US 2011/0068423 A1
(43) Pub. Date: Mar. 24, 2011

(54) PHOTODETECTOR WITH WAVELENGTH DISCRIMINATION, AND METHOD FOR FORMING THE SAME AND DESIGN STRUCTURE

(75) Inventor: John M. Aitken, Essex Junction, VT (US)

(73) Assignee: INTERNATIONAL BUSINESS MACHINES CORPORATION, Armonk, NY (US)

(21) Appl. No.: 12/562,362

(22) Filed: Sep. 18, 2009

(51) Int. Cl. H01L 31/14; G06F 17/50; H01L 31/18; H01L 31/0232

(52) U.S. Cl. 257/432; 438/59; 257/443; 257/E31.127; 257/E31.097; 716/103; 716/100; 716/139; 716/126

(57) ABSTRACT

The disclosure relates generally to photodetectors and methods of forming the same, and more particularly to optical photodetectors. The photodetector includes a waveguide having a radius that controls the specific wavelength or specific range of wavelengths being detected. The disclosure also relates to a design structure of the aforementioned.

### BACKGROUND

1. Technical Field

The disclosure relates generally to photodetectors and methods of forming the same, and more particularly to optical photodetectors. The disclosure also relates to a design structure of the aforementioned.

2. Background Art

Image sensors have been used in digital cameras and a wide variety of other imaging devices. The image sensor is typically a complementary metal-oxide semiconductor (CMOS) sensor or a charged coupled device (CCD). CMOS image sensors are increasingly being used in imaging devices instead of CCDs because of lower power consumption, lower system cost, and the ability to randomly access image data. To detect particular colors/wavelengths or frequencies, known CMOS imaging technology requires semiconductors with different band gaps, a semiconductor with various color input filters formed from dye impregnated resists, polymer-based color filters, and/or Fabry-Perot interference layers. Also, additional components such as microlenses are often needed.

### SUMMARY

An aspect of the present invention relates to a photodetector comprising: a semiconductor substrate; a photoconversion device within the semiconductor substrate; a first layer over the photoconversion device; a second layer over the first layer; and a waveguide having a radius r positioned over the first layer and the photoconversion device, wherein r is in a range from approximately 1,000 angstroms (Å) to approximately 4,000 Å.

A second aspect of the present invention relates to an image sensor comprising: an array of photodetectors, each photodetector comprising: a semiconductor substrate; a photoconversion device within the semiconductor substrate; a first layer over the photoconversion device; a second layer over the first layer; and

a waveguide having a radius r positioned over the first layer and the photoconversion device, wherein r is in a range from approximately 1,000 angstroms (Å) to approximately 4,000 Å.

A third aspect of the present invention relates to a method of forming a photodetector comprising: forming a photoconversion device within a semiconductor substrate; forming a first layer over the photoconversion device; forming a second layer over the first layer; and forming a waveguide having a radius r positioned over the first layer and the photoconversion device, wherein r is in a range from approximately 1,000 angstroms (Å) to approximately 4,000 Å.

A fourth aspect of the present invention relates to a design structure embodied in a machine readable medium for designing, manufacturing, or testing a photodetector, the design structure comprising: a semiconductor substrate; a photoconversion device within the semiconductor substrate; a first layer over the photoconversion device; a second layer over the first layer; and a waveguide having a radius r positioned over the first layer and the photoconversion device, wherein r is in a range from approximately 1,000 angstroms (Å) to approximately 4,000 Å.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 depicts an embodiment of a photodetector, in accordance with the present invention;

FIG. 2 depicts an embodiment of an image sensor, in accordance with the present invention; and

FIG. 3 depicts a flow diagram of a design process used in photodetector design, manufacture, and/or test, in accordance with the present invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

It has been discovered that using semiconductors with different band gaps, a semiconductor with various color input filters formed from dye impregnated resists, polymer-based color filters, and/or Fabry-Perot interference layers as well as components such as microlenses in semiconductor imager applications present several undesirable constraints for high volume manufacturing. Examples of the constraints are the difficulty in achieving uniform chemical properties in the in the polymer color filters, uniform filter thickness, stability of the color filters in the semiconductor imager and uniform positioning of color filters in a semiconductor imager. Conventional polymer color filters, Fabry-Perot interference layers, and microlenses also complicate the manufacturing process because they are separate components that must be integrated into the semiconductor imaging product.

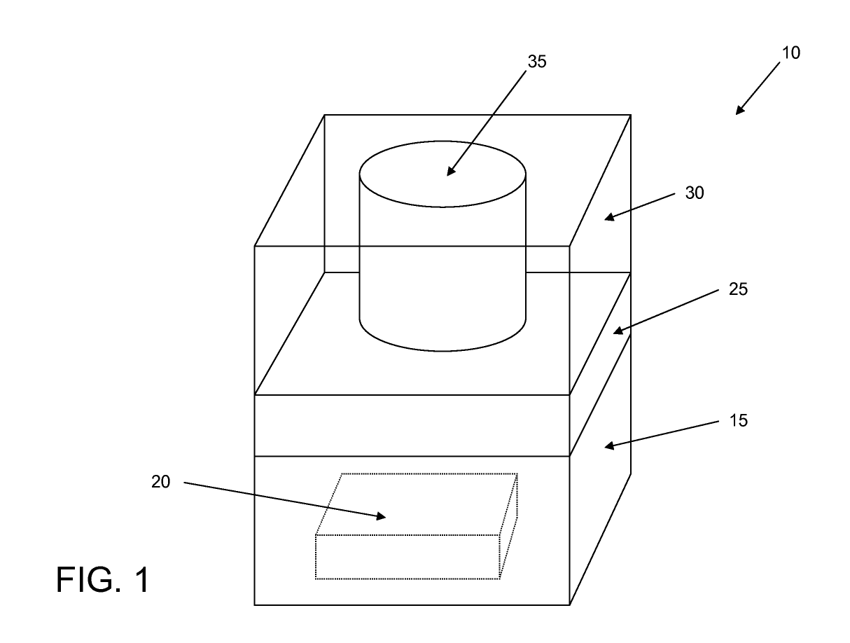

An embodiment of a photodetector is presented in accordance with the present invention. Referring to FIG. 1, a photodetector 10 is provided having a semiconductor substrate 15, a photoconversion device 20, a first layer 25, a second layer 30, and a waveguide 35.

Semiconductor substrate 15 may be comprised of but not limited to silicon, germanium, silicon germanium, silicon carbide, and those consisting essentially of one or more Group III-V compound semiconductors having a composition defined by the formula Alₓ₁Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Semiconductor substrate 15 may also be comprised of Group II-VI compound semiconductors having a composition Zn_{A1} Cd_{A2}Se_{B1}Te_{B2}, where A1, A2, B1, and B2 are relative proportions each greater than or equal to zero and A1+A2+B1+B2=1 (1 being a total mole quantity). The processes to provide semiconductor substrate 15, as illustrated and described, are well known in the art and thus, no further description is necessary. In an embodiment of the present invention, semiconductor substrate 15 may comprise a p-type doped substrate. Examples of p-type dopants include but are not limited to boron (B), indium (In), and gallium (Ga).

Semiconductor substrate 15 has within it photoconversion device 20. In an embodiment of the present invention, photoconversion device 20 may comprise a photogate, photoconductor, or a photodiode. The aforementioned, as illustrated and described, are well known in the art and thus, no further description is necessary. In an embodiment of the present invention photoconversion device 20 is a photodiode. In another embodiment, the photodiode may be a p+/n diode. In another embodiment, the photodiode may be a n+/p diode. The processes to provide photoconversion device 20 within semiconductor substrate 15, as illustrated and described, are well known in the art and thus, further description also is not necessary.

First layer 25 is a dielectric material that is deposited over photoconversion device 20. In an embodiment of the present invention, first layer 25 may comprise a material selected from the group consisting of silicon oxide (SiO₂), silicon nitride (Si₃N₄), hafnium oxide (HfO₂), hafnium silicon oxide (HfSiO), hafnium silicon oxynitride (HfSiON), zirconium oxide (ZrO₂), zirconium silicon oxide (ZrSiO), zirconium silicon oxynitride (ZrSiON), aluminum oxide (Al₂O₃), titanium oxide (Ti₂O₅) and tantalum oxide (Ta₂O₅). In another embodiment, first layer 25 may comprise an n-type doped material. Examples of n-type dopants include but are not limited to phosphorous (P), arsenic (As), and antimony (Sb). In an embodiment of the present invention, first layer 25 may have a dielectric constant (k) in a range from approximately 1,000 angstroms (Å) to approximately 10,000 Å.

First layer 25 is deposited over photoconversion device 20 and/or semiconductor substrate 15 using any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation. First layer 25 has thicknesses that may vary, but in one embodiment, the thickness is in a range from approximately 1,000 angstroms Å) to 10,000 Å.

In an embodiment of the present invention, semiconductor substrate 15 is an n-type doped substrate and first layer 25 is a p-typed doped dielectric material. Various embodiments of the aforementioned are described supra.

Second layer 30 is comprised of a dielectric material or metal that is deposited over first layer 25. In an embodiment of the present invention, second layer 25 may be comprised of the same dielectric materials described supra for first layer 25. In another embodiment, second layer 30 may be an opaque dielectric material. In another embodiment, second layer 30 is translucent. In another embodiment, second layer 30 is comprised of a metal selected from the group consisting of tungsten (W), tantalum (Ta), aluminum (Al), ruthenium (Ru), platinum (Pt), etc. or any electrically conductive compound including but not limited to titanium nitride (TiN), titanium carbide (TiC), tantalum carbide (TaC), tantalum nitride (TaN), tantalum carbon nitride (TaCN), tantalum carbide oxynitride (TaCNO), ruthenium oxide (RuO₂), nickel silicide (NiSi), nickel-platinum silicide (NiPtSi), etc. and combinations and multi-layers thereof.

When second layer 30 comprises a dielectric material, it is deposited on first layer 25 using any of the techniques described supra for the deposition of first layer 25 or later developed techniques appropriate for the material to be deposited. When second layer 30 comprises a metal or an electrically conductive compound, it is deposited using any now known or later developed techniques appropriate for the metal or the electrically conductive compound to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation.

Waveguide 35 is positioned over first layer 25 and photoconversion device 20. Waveguide 35 propagates electromagnetic radiation with a frequency (f)>f_{co} and wavelengths (L)<L_{co}, where co denotes a cutoff, to photoconversion device 20. L_{co} is dependent on waveguide radius (r) and is given by the equation L_{co}=2.6r. Only radiation with wavelengths shorter than L_{co} will propagate through waveguide 35 to photoconversion device 20. Waveguide 35 may be comprised of a dielectric material as described supra or air. When waveguide 35 comprises a dielectric material, the refractive index of the dielectric material must be less than the refractive index of second layer 30 to allow propagation of electromagnetic radiation.

Waveguide 35 may have a radius in a range from approximately 1,000 Å to approximately 4,000 Å. When the waveguide radius is approximately 4,000 Å, electromagnetic radiation shorter than 10,000 Å (red, green, and blue light) is propagated through waveguide 35 to photoconversion device 20. When the waveguide radius is approximately 2,000 Å, radiation shorter than 5,000 Å (green and blue light) is propagated through waveguide 35. When waveguide radius is approximately 1,000 Å, radiation shorter than 2,500 Å (blue light) is propagated through waveguide 35 to photoconversion device 20. Selecting the radius of waveguide 35 allows one to control the specific wavelength or specific range of wavelengths being detected by photoconversion device 20.

In an embodiment of the present invention, waveguide 35 and second layer 30 may be comprised of a dielectric material wherein the refractive index of second layer 30 is greater than the dielectric material of waveguide 35. In another embodiment, waveguide 35 may be comprised of a dielectric material and second layer 30 may be comprised of a metal or electrically conducting compound. In another embodiment, waveguide 35 may be comprised of air and second layer 30 may be comprised of a metal or electrically conducting compound.

In an embodiment of the present invention, photodetector 10 may be incorporated in a digital camera. In another embodiment, photodetector 10 may be incorporated in a light spectrum analyzer. In another embodiment, photodetector 10 may be an optical photodetector.

Photodetector 10 is devoid of an element or combination of elements selected from the group consisting of a polymer color filter, a dye impregnated resist, and a Fabry-Perot interference layer.

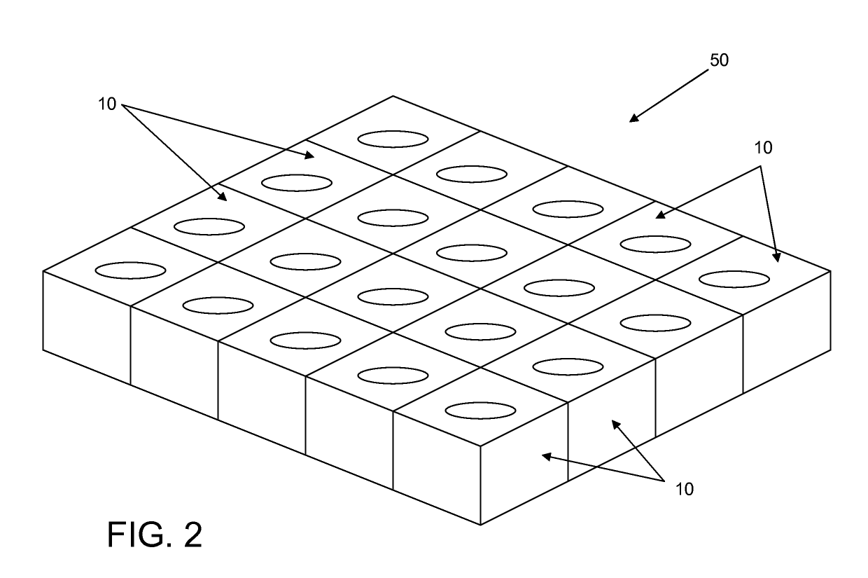

An embodiment of an image sensor is presented in accordance with the present invention. Referring to FIG. 2, an image sensor 50 is provided having an array of photodetectors 10, see FIG. 1. The array comprises a two-dimensional organization of photodetectors 10 in rows and columns. Photodetectors 10 each comprise a semiconductor substrate 15, a photoconversion device 20, a first layer 25, a second layer 30, and a waveguide 35. The description of photodetectors 10 and their elements 15, 20, 25, and 35, and various embodiments of each are provided supra. In an embodiment of the present invention, each photodetector 10 may be operatively connected to an active amplifier and the array of photodetectors 10 may be operatively connected to an integrated circuit. The processes to operatively connect photodetector 10 to an active amplifier and the array of photodetectors 10 to the integrated circuit, as described, are well known in the art and thus, no further description is necessary.

In another embodiment, the image sensor 50 may comprise photodetectors 10 wherein each photodetector 10 shares the same characteristics or each photodetector 10 independently has different characteristics such as radius of waveguide 35, the composition of first layer 25, the composition of second layer 30, the composition of waveguide 35, photoconversion device 20, etc.

In an embodiment of the present invention, image sensor 50 may be a CMOS image sensor. In another embodiment, image sensor 50 may be a CCD image sensor. In an embodiment of the present invention, image sensor 50 may be incorporated in a digital camera. In another embodiment, image sensor 50 may be incorporated in a light spectrum analyzer. In another embodiment, image sensor 50 may be devoid of an element or combination of elements selected from the group consisting of a polymer color filter, a dye impregnated resist, and a Fabry-Perot interference layer.

An embodiment of a method of forming a photodetector is presented in accordance with the present invention. Referring to FIG. 1, a method of forming a photodetector 10 is provided having the steps of forming a photoconversion device 20 within a semiconductor substrate 15, forming a first layer 25 over photoconversion device 20, forming a second layer 30 over first layer 25, and forming a waveguide 35 having a radius r positioned over first layer 25 and photoconversion device 20, wherein r is in a range from approximately 1,000 Å to approximately 4,000 Å.

A semiconductor substrate 15 is provided. The description of semiconductor substrate 15 and various embodiments are provided supra. A photoconversion device 20 is formed within semiconductor substrate 15. The processes to form photodetector 10 within semiconductor substrate 15, as described, are well known in the art and thus, no further description is necessary. In an embodiment of the present invention, photoconversion device 20 may be selected from the group consisting of a photogate, a photoconductor, and a photodiode. In another embodiment, photoconversion device 20 formed within semiconductor substrate 15 is the photodiode.

First layer 25 is formed over photoconversion device 20 and/or semiconductor substrate 15 by deposition using any now known or later developed techniques appropriate for the material to be deposited as described supra. The description of first layer 25 and various embodiments also are provided supra.

Second layer 30 is formed over first layer 25 by deposition using any now known or later developed techniques appropriate for the material to be deposited as described supra. The description of second layer 25 and various embodiments also are provided supra.

A waveguide 35 having a radius r positioned over first layer 25 and photoconversion device 20 is formed, wherein r is in a range from approximately 1,000 angstroms Å to approximately 4,000 Å. Waveguide 35 is formed by using any now known or later developed techniques appropriate for waveguide 35 formation. Examples include but are not limited to forming waveguide 35 into second layer 25 via photolithography, routing, punching, laser ablation, etching, etc.

The radius of waveguide 35 may be formed in a range approximately 1,000 Å to approximately 4,000 Å. In an embodiment of the present invention, the radius may be approximately 4,000 Å. In another embodiment, the radius may be approximately 2,000 Å. In another embodiment, the radius may be approximately 1,000 Å. One having ordinary skill in the art will recognize now known or later developed techniques that are used to selectively choose the radius of waveguide 35 during waveguide 35 forming step. As described supra, selecting the radius of waveguide 35 allows one to control the specific wavelength or specific range of wavelengths being detected by photoconversion device 20. One having ordinary skill in the art also will recognize that selecting a particular waveguide 35 radius to control the specific wavelength or range of wavelengths being detected is not limited to the radii or ranges of radii described supra but selecting is optimized with routine experimentation to determine the appropriate radius/radii length that corresponds to the detection of a specific wavelength or specific range of wavelengths.

A design structure embodied in a machine readable medium for designing, manufacturing, or testing photodetector(s) is presented in accordance with the present invention. The design structure comprises a semiconductor substrate; a photoconversion device within the semiconductor substrate; a first layer over the photoconversion device; a second layer over the first layer; and a waveguide having a radius r positioned over the first layer and the photoconversion device, wherein r is in a range from approximately 1,000 Å to approximately 4,000 Å.

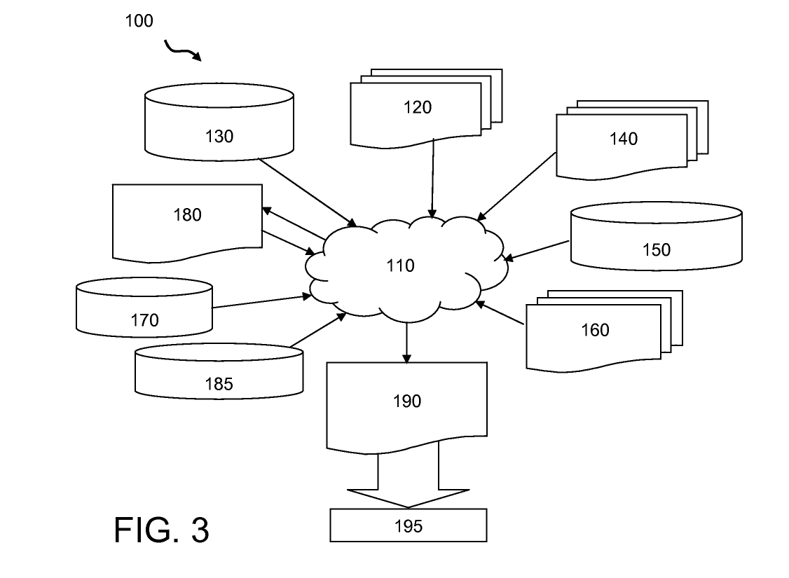

Referring to FIG. 3, a block diagram of an exemplary design flow 100 used for example, in photodetector design, manufacturing, and/or test is shown. Design flow 100 may vary depending on the type of IC being designed. For example, a design flow 100 for building an application specific IC (ASIC) may differ from a design flow 100 for designing a standard component. Design structure 120 is preferably an input to a design process 110 and may come from an IP provider, a core developer, or other design company or may be generated by the operator of the design flow, or from other sources. Design structure 120 comprises an embodiment of the invention as shown in FIG. 1 and FIG. 2 in the form of schematics or HDL, a hardware-description language (e.g., Verilog, VHDL, C, etc.). Design structure 120 may be contained on one or more machine readable medium. For example, design structure 120 may be a text file or a graphical representation of an embodiment of the invention as shown in FIG. 1 and FIG. 2. Design process 110 preferably synthesizes (or translates) an embodiment of the invention as shown in FIG. 1 and FIG. 2 into a netlist 180, where netlist 180 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which netlist 180 is resynthesized one or more times depending on design specifications and parameters for the circuit.

Design process 110 may include using a variety of inputs; for example, inputs from library elements 130 which may house a set of commonly used elements, circuits, and devices, including models, layouts, and symbolic representations, for a given manufacturing technology (e.g., different technology nodes, 32 nm, 45 nm, 90 nm, etc.), design specifications 140, characterization data 150, verification data 160, design rules 170, and test data files 185 (which may include test patterns and other testing information). Design process 110 may further include, for example, standard circuit design processes such as timing analysis, verification, design rule checking, place and route operations, etc. One of ordinary skill in the art of integrated circuit design can appreciate the extent of possible electronic design automation tools and applications used in design process 110 without deviating from the scope and spirit of the invention. The design structure of the invention is not limited to any specific design flow.

Design process 110 preferably translates an embodiment of the invention as shown in FIG. 1 and FIG. 2, along with any additional integrated circuit design or data (if applicable), into a second design structure 190. Design structure 190 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 190 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce an embodiment of the invention as shown in FIG. 1 and FIG. 2. Design structure 190 may then proceed to a stage 195 where, for example, design structure 990: proceeds to tape-out, is released to manufacturing, is released to a mask house, is sent to another design house, is sent back to the customer, etc.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A photodetector comprising:
a semiconductor substrate;
a photoconversion device within the semiconductor substrate;
a first layer over the photoconversion device;
a second layer over the first layer; and
a waveguide having a radius r positioned over the first layer and the photoconversion device, wherein r is in a range from approximately 1,000 angstroms (Å) to approximately 4,000 Å.

2. The photodetector of claim 1, wherein the first layer comprises a dielectric layer.

3. The photodetector of claim 1, wherein the second layer comprises a dielectric layer or a metal layer.

4. The photodetector of claim 1, wherein the photoconversion device is selected from the group consisting of a photogate, a photoconductor, and a photodiode.

5. The photodetector of claim 1, wherein the photodetector is incorporated in a digital camera.

6. The photodetector of claim 1, wherein the photodetector is incorporated in a light spectrum analyzer.

7. The photodetector of claim 1, wherein the photodetector is devoid of an element selected from the group consisting of a polymer color filter, a dye impregnated resist, and a Fabry-Perot interference layer.

8. An image sensor comprising:
an array of photodetectors, each photodetector comprising:
a semiconductor substrate;
a photoconversion device within the semiconductor substrate;
a first layer over the photoconversion device;
a second layer over the first layer; and
a waveguide having a radius r positioned over the first layer and
the photoconversion device, wherein r is in a range from approximately 1,000 angstroms (Å) to approximately 4,000 Å.

9. The image sensor of claim 8, wherein the image sensor comprises a CMOS image sensor or a CCD image sensor.

10. The image sensor of claim 8, wherein the first layer comprises a dielectric layer.

11. The image sensor of claim 8, wherein the second layer comprises a dielectric layer or a metal layer.

12. The image sensor of claim 8, wherein the photoconversion device is selected from the group consisting of a photogate, a photoconductor, and a photodiode.

13. A method of forming a photodetector comprising:
forming a photoconversion device within a semiconductor substrate;
forming a first layer over the photoconversion device;
forming a second layer over the first layer; and
forming a waveguide having a radius r positioned over the first layer and the photoconversion device, wherein r is in a range from approximately 1,000 angstroms (Å) to approximately 4,000 Å.

14. The method of claim 13, wherein the first layer comprises a dielectric layer.

15. The method of claim 13, wherein the second layer comprises a dielectric layer or a metal layer.

16. The method of claim 13, wherein the photoconversion device is selected from the group consisting of a photogate, a photoconductor, and a photodiode.

17. A design structure embodied in a machine readable medium for designing, manufacturing, or testing a photodetector, the design structure comprising:
a semiconductor substrate;
a photoconversion device within the semiconductor substrate;
a first layer over the photoconversion device;
a second layer over the first layer; and
a waveguide having a radius r positioned over the first layer and the photoconversion device, wherein r is in a range from approximately 1,000 angstroms (Å) to approximately 4,000 Å.

18. The design structure of claim 17, wherein the design structure comprises a netlist.

19. The design structure of claim 17, wherein the design structure resides on storage medium as a data format used for the exchange of layout data of integrated circuits.

20. The design structure of claim 17, wherein the design structure includes at least one of test data, characterization data, verification data, or design specifications.
